(19) United States
(12) Patent Application Publication
(10) Pub. No.: US 2010/0078865 A1
(43) Pub. Date: Apr. 1, 2010

(54) Sheet clamping apparatus

(76) Inventors: Yung Shuen PAN, Shulin City (TW); Chia-Hao YANG, Shulin City (TW)

Correspondence Address: SINORICA, LLC, 2275 Research Blvd., Suite 500, ROCKVILLE, MD, 20850, US

(21) Appl. No.: 12/323,581

(22) Filed: Nov. 26, 2008

(30) Foreign Application Priority Data
Sep. 26, 2008 (TW) 097137048

(51) Int. Cl. H01L 21/683

(52) U.S. Cl. 269/61; 269/66; 269/317

(57) ABSTRACT

The present invention discloses a sheet clamping apparatus for a reticle, a wafer, a glass substrate, a LCD panel et al. The apparatus comprises a pair of brackets, each bracket having at least one cam groove thereon for defining a movement route by two opposing sides of the cam groove, and one end of each bracket being joined with a connecting frame. One end of a clamping arm is joined with each cam groove, and the other end of the clamping arm is clamping the sheet (ex: a reticle, a wafer, a glass substrate, a LCD panel et al.). The characteristic of the sheet clamping apparatus is that: on the other end of each clamping arm is formed with a clamping head with recess, and at least a pair of rollers are disposed on the recess of clamping head for stably clamping the reticle or a semiconductor component stored in the pod.

### BACKGROUND OF THE INVENTION

1. Field of the Invention

The present invention is related to a sheet clamping apparatus, and more particularly, to a clamping apparatus used for clamping component such as a reticle, a wafer, a glass substrate, and a LCD panel in the process, with which the reticle or semiconductor component stored in the pod can be stably clamped.

2. Description of the Prior Art

In the semiconductor process, the step of cleaning is important and indispensable, the main objective of which is to thoroughly remove all organic materials, contaminants, and chemical residuals that remain on the surface of semiconductor component or reticle. Otherwise, once contaminated semiconductor component or reticle is introduced into further manufacturing process, negative impact on product yield and production capability will be caused.

And optical lithography plays an important role in the semiconductor process since everything related to pattern definition relies on optical lithography. In the application of optical lithography in semiconductor industry, designed circuit are manufactured into light transmissible reticle in specific form for light source to pass through the reticle and project onto the silicon wafer for exposure and formation of specific pattern. In the process of which multiple procedures of wet process and further process are alternatively performed. When the two processes are alternatively switched, component such as semiconductor component or reticle needs to be clamped out from the storage carrier or the pod for facilitating the cleaning and removal of chemicals or water or any other residuals remaining on semiconductor component or reticle to avoid affecting the following process. Meantime, dust particles or other particles are generated during the transportation or storage of semiconductor component or reticle should also be thoroughly cleaned to avoid any possible affect on the following process.

Semiconductor component or reticle needs to go through air drying procedure according to different process requirements. Therefore when the procedure is performed, semiconductor component or reticle needs to be taken out and stably clamped to facilitate operation. And particularly because reticle is fairly valuable, each step in the operating process needs to be performed with extraordinary care, especially when taking reticle out of the storage carrier for performing operation to avoid occurrence of any damage that will lead to economic loss. However in conventional semiconductor apparatus, the design of clamping apparatus is not stable enough and the flow of operating procedures is not smooth enough either, which are thus not able to meet different kinds of operation demands and result in inconvenience in the process and may also increase the percentage of damage of semiconductor component or reticle.

### BRIEF SUMMARY OF THE INVENTION

In order to solve the aforementioned problems, one objective of the present invention is to provide a sheet clamping apparatus for stably clamping reticle or semiconductor component stored in the pod.

Another objective of the present invention is to provide a sheet clamping apparatus, on the clamping head with recess of which are disposed with a pair of multiple pairs of rollers, for enhancing stability and tightness when clamping the sheet and preventing the sheet from being damaged due to improper or unstable clamping.

Still another objective of the present invention is to provide a sheet clamping apparatus, the roller is disposed on the clamping head of which being made of PEEK or elastic rubber material, for greatly reduce particles generated due to friction and effecting cleanliness of the sheet.

### BRIEF DESCRIPTION OF THE DRAWINGS

The invention as well as a preferred mode of use, further objectives and advantages thereof will best be understood by reference to the following detailed description of illustrative embodiments when read in conjunction with the accompanying drawings, wherein:

FIG. 1 is a frontal view of sheet clamping apparatus of the present invention;

FIG. 2 is an isometric view of clamping arm of the present invention;

FIG. 3 is a frontal view of sheet clamping apparatus of the present invention;

FIG. 4 is a frontal view of sheet clamping apparatus of the present invention;

FIG. 5 is a view of gear module structure of the present invention.

### DESCRIPTION OF THE PREFERRED EMBODIMENTS

The present invention discloses a sheet clamping apparatus, and more particularly, a clamping apparatus used for clamping component such as a reticle, a wafer, a glass substrate, and a LCD panel in the manufacturing process, with which reticle or semiconductor component stored in the pod can be stably clamped. In the present invention, some details of manufacturing or operating processes of clamping apparatus are achieved by applying conventional art, and therefore are not completed depicted in below description. And the drawings is referred to in the following are not made according to the actual related sizes, the function of which is only to express and illustrate characteristics of the present invention.

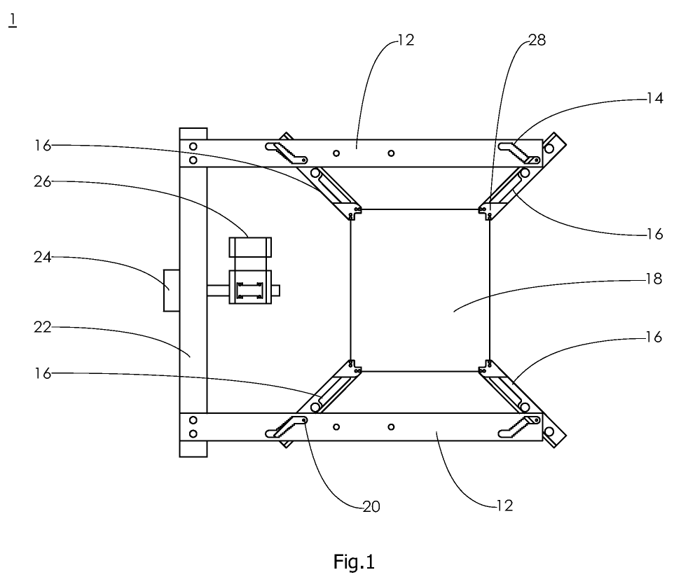

First, referring to FIG. 1, which is a view of a preferred embodiment of sheet clamping apparatus according to the present invention. As shown in FIG. 1, the sheet clamping apparatus 1 comprises a pair of brackets 12, one end of each bracket 12 being joined with a connecting frame 22 and on each bracket 12 being disposed with at least one cam groove 14 for defining a movement route by two opposing sides of the cam groove 14. One end of a clamping arm 16 is joined with each cam groove 14, and the other end of the clamping arm 16 is clamping the sheet 18. The characteristic of the sheet clamping apparatus 1 is that: on the other end of each clamping arm 16 is formed with a clamping head 28 with recess 282, and at least a pair of rollers 30 are disposed on the recess 282 of clamping head 28. Wherein the aforementioned sheet 18 can be component such as a reticle, a wafer, a glass substrate, and a LCD panel.

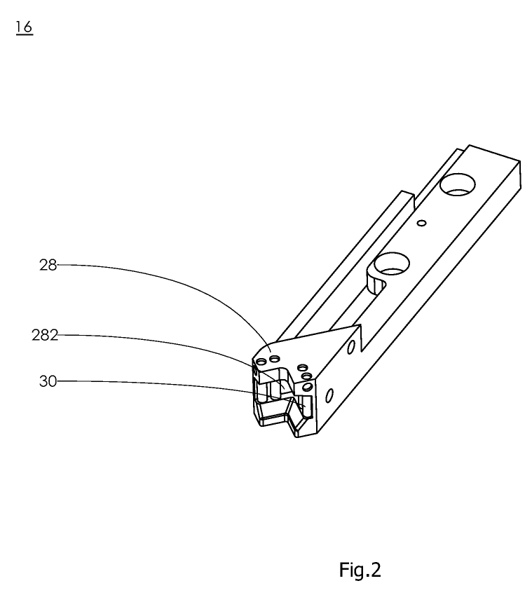

Referring to FIG. 2, which is a detailed view of clamping arm of the present invention. The clamping head 28 of the clamping arm 16 includes a recess 282 for clamping or releasing four corners of the sheet 18. One pair or multiple pairs of rollers 30 are further disposed on the recess 282. Wherein the recess 282 can be roughly in mutually symmetrical shape, for example, being v-shaped, right-angle shaped, or curved shaped, and therefore the pair of rollers 30 can be respectively disposed at mutually symmetrical positions of the recess 282 for enhancing the stability and tightness in clamping the sheet 18 and preventing the sheet 18 from being damaged due to improper or unstable clamping. Moreover, the pair of rollers 30 are made of polymer material, and such polymer material is mostly preferred to be PEEK or elastic rubber material, with which the particles are generated due to friction and effecting cleanliness of the sheet can be greatly reduced.

Still referring to FIG. 1, the movement route is defined by two opposing sides of the cam groove 14 of sheet clamping apparatus 1 can be S-shaped, Z-shaped, or parallelogram-shaped. And the clamping arm 16 further includes a roller follower 20 disposed at the part where the clamping arm 16 is joined with the cam groove 14 with part of it extending beyond the cam groove 14. Therefore when the sheet clamping apparatus 1 operates, the clamping arm 16 can be drawn by the roller follower 20 to move along the movement route of cam groove 14 for the clamping head 28 to move farther away from or nearer to the sheet 18 and thus achieving the objective of clamping or releasing the sheet 18. The sheet clamping apparatus 1 further includes a power source 26 for driving these clamping arms 16, and this power source 26 can be a stepper motor. Moreover, a rotation portion 24 is further disposed on the connecting frame 22 of sheet clamping apparatus 1, wherein the rotation portion 24 is equipped with rollback mechanism for rotating coupled connecting frames 22 at least 180 degrees or at specific angle.

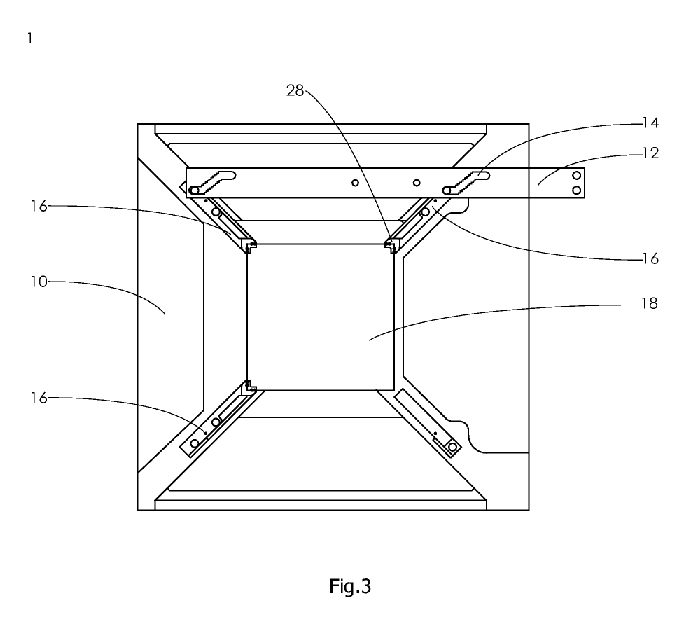

Then, referring to FIG. 3, which is a view of another preferred embodiment of sheet clamping apparatus according to the present invention. As shown in FIG. 3, the sheet clamping apparatus 1 mainly comprises at least one bracket 12, one end of which is fixedly disposed on a main body 10 and on which is disposed with at least a cam groove 14. Each bracket 12 has at least one cam groove 14 disposed thereon for defining a movement route by two opposing sides of each cam groove 14. One end of a clamping arm 16 is joined with each cam groove 14, and the other end of clamping arm 16 is clamping the sheet 18, wherein the characteristic of sheet clamping apparatus 1 is in that: a clamping head 28 with recess 282 is formed on the other end of each clamping arm 16, and at least a pair of rollers 30 are disposed on the recess 282 of the clamping head 28. Wherein the aforementioned sheet 18 can be component such as a reticle, a wafer, a glass substrate, and a LCD panel, and the detailed view of clamping arm 16 is as shown in FIG. 2, the contents of which are the same as what is already described above and will not be repeated.

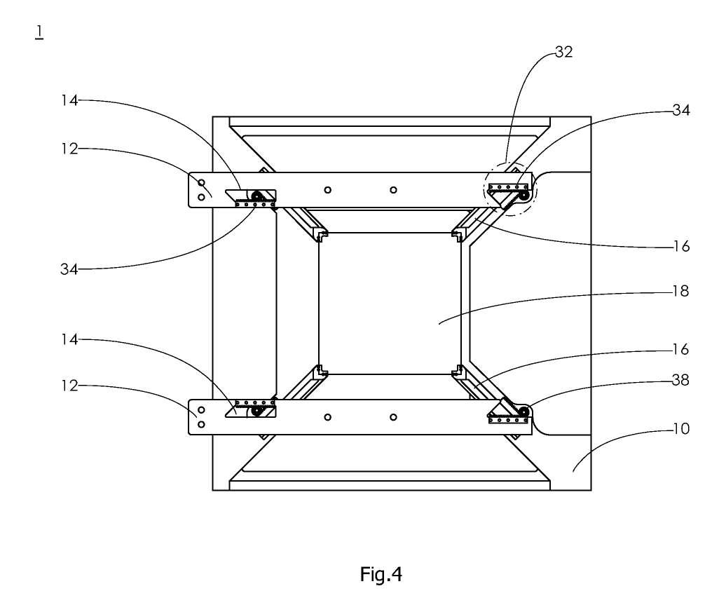

Referring to FIG. 4, which is a view of still another preferred embodiment of sheet clamping apparatus according to the present invention. According to the component is disclosed in FIG. 3, the clamping arm 16 in FIG. 4 further comprises a gear wheel module 32 disposed at the part where the clamping arm 16 is joined with the cam groove 14.

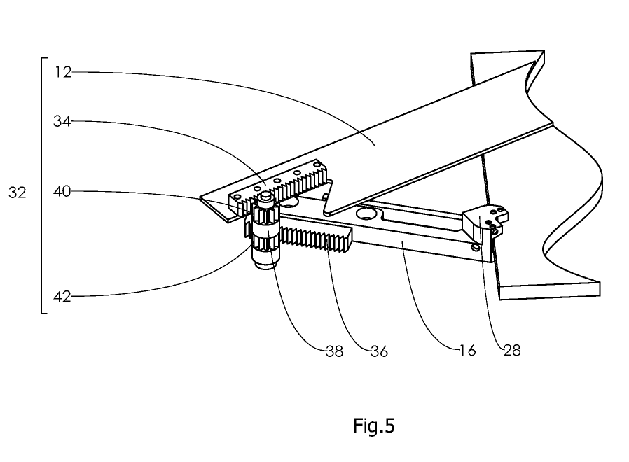

Then, referring to FIG. 5, which is a detailed view of gear wheel module structure of the present invention. As shown in FIG. 5, the gear wheel module 32 is composed of a first rack 34, a second rack 36, and a rotation gear with gear groove 38. The first rack 34 is disposed on the bracket 12, the second rack 36 is disposed on the clamping arm 16, and one end of the rotation gear 38 is fixedly disposed on the main body 10, wherein the gear groove of rotation gear 38 is composed of a first gear portion 40 and a second gear portion 42, the first rack 34 and the first gear portion 40 meshing with each other and the second rack 36 and the second gear portion 42 meshing with each other.

Since one end of the rotation gear 38 is fixedly disposed on the main body 10, and part of it extends beyond the cam groove 14, therefore when the sheet clamping apparatus 1 operates, the clamping arm 16 can be drawn by the rotation gear 38 to move along the movement route of cam groove 14 for the clamping head 28 to move farther away from or nearer to the sheet 18 and thus achieving the objective of clamping or releasing the sheet 18.

The present invention has been clearly described as above with illustration of each embodiment and related drawings. However, what should be understood by those who are skilled in the art is that, each embodiment of the present invention as herein described is only exemplary rather than limiting. Namely, all modifications and similar arrangements of components as mentioned above made without departing from the spirit and scope of the present invention should be covered by the present invention. And the scope of the present invention is only determined by the appended claims which are to be accorded the broadest interpretation

What is claimed is:

1. A sheet clamping apparatus, comprising a pair of brackets, one end of each of said brackets joining with a connecting frame, at least a cam groove being disposed on each of said brackets and a movement route being defined by two opposing sides of each of said cam groove, one end of a clamping arm being joined with each of said cam groove and the other end of said clamping arm being clamping said sheet, wherein the characteristic of said sheet clamping apparatus is in that:
a clamping head with recess being formed on said other end of each of said clamping arm, and at least a pair of rollers being disposed on said recess of said clamping head.

2. The sheet clamping apparatus according to claim 1, wherein the shape of said recess is selected from the group consisting of: v-shape, right-angle shape, and curved shape.

3. The sheet clamping apparatus according to claim 1, wherein said roller is made of polymer material.

4. The sheet clamping apparatus according to claim 3, wherein said polymer material is selected from the group consisting of: PEEK and elastic rubber.

5. The sheet clamping apparatus according to claim 1, wherein said movement route of said cam groove is selected from the group consisting of: S-shape, Z-shape, and parallelogram-shape.

6. The sheet clamping apparatus according to claim 1, further comprising a power source for driving said plurality of clamping arms.

7. The sheet clamping apparatus according to claim 6, wherein said power source is a stepper motor.

8. The sheet clamping apparatus according to claim 1, wherein a rotation portion is disposed on said connecting frame.

9. The sheet clamping apparatus according to claim 1, wherein said sheet is selected from the group consisting of: reticle, wafer, glass substrate, and LCD panel.

10. The sheet clamping apparatus according to claim 1, wherein said clamping arm further includes a roller follower disposed at the part where said clamping arm is joined with said cam groove.

11. A sheet clamping apparatus, comprising a bracket, said bracket being fixedly disposed on a main body and at least a cam groove being disposed on said bracket, a movement route being defined by two opposing sides of each of said cam groove, one end of a clamping arm being joined with each of said cam groove and the other end of said clamping arm being clamping said sheet, wherein the characteristic of said sheet clamping apparatus is in that:
a clamping head with recess being formed on said other end of each of said clamping arm, and at least a pair of rollers being disposed on said recess of said clamping head.

12. The sheet clamping apparatus according to claim 11, wherein shape of said recess is selected from the group consisting of: v-shape, right-angle shape, and curved shape.

13. The sheet clamping apparatus according to claim 11, wherein said movement route of said cam groove is selected from the group consisting of: S-shape, Z-shape, and parallelogram-shape.

14. The sheet clamping apparatus according to claim 11, wherein said clamping arm further includes a roller follower disposed at the part where said clamping arm is joined with said cam groove.

15. The sheet clamping apparatus according to claim 11, wherein said clamping arm further includes a gear module disposed at part where said clamping arm is joined with said cam groove.

16. The sheet clamping apparatus according to claim 15, wherein said gear module is composed of a first rack, a second rack, and a rotation gear with gear groove.

17. The sheet clamping apparatus according to claim 16, wherein said first rack is disposed on said bracket.

18. The sheet clamping apparatus according to claim 16, wherein said second rack is disposed on said switching arm.

19. The sheet clamping apparatus according to claim 16, wherein said rotation gear is with one end fixedly disposed on said main body.

20. The sheet clamping apparatus according to claim 16, wherein said gear groove of said rotation gear is composed of a first gear portion and a second gear portion.
